(19) United States
(12) Patent Application Publication
(10) Pub. No.: US 2009/0146070 A1
(43) Pub. Date: Jun. 11, 2009

(54) X-RAY IMAGING MATRIX WITH LIGHT GUIDES AND INTELLIGENT PIXEL SENSORS, RADIATION OR HIGH ENERGY PARTICLE DETECTOR DEVICES THAT CONTAIN IT, ITS FABRICATION PROCESS AND ITS USE

(75) Inventors: Jose Gerardo Vieira Da Rocha, Famalicao, (PT); Senentxu Lanceros-Mendez, Braga (PT)

Correspondence Address: SUGHRUE MION, PLLC, 2100 PENNSYLVANIA AVENUE, N.W., SUITE 800, WASHINGTON, DC, 20037, US

(73) Assignee: UNIVERSIDADE DO MINHO, Braga (PT)

(21) Appl. No.: 12/090,917

(22) PCT Filed: Sep. 13, 2006
(86) PCT No.: PCT/IB06/53268

§ 371 Date: Apr. 21, 2008

(30) Foreign Application Priority Data
Oct. 20, 2005 (IT) 103370

(51) Int. Cl. G01T 1/20

(52) U.S. Cl. 250/370.09; 250/370.11

(57) ABSTRACT

The present invention refers to a radiation or high energy particles detector, which can be used in obtaining digital radiographic images. The detector is composed of two parts: a scintillator matrix (30) embedded in walls manufactured from a reflector material (10), and a matrix of image elements (pixels), where each element is constituted by a photodetector (21) and an analog to digital converter. The walls manufactured from the reflector material (10) form light guides that prevent the dispersion of the visible light produced by the scintillators (30) and the consequent interference between each pixel and its neighbors.

### FIELD OF THE INVENTION

The present invention belongs to the field of the detection of digital x-rays images, another type of radiation or high energy particles, particularly relevant in the medical areas and non destructive industrial tests. The present invention allows obtaining high quality and easy processing images, while reducing the amount of radiation necessary to obtain the images.

### BACKGROUND OF THE INVENTION

When a radiation beam, for example in the x-ray spectrum, crosses a body, the photons that constitute the beam interact with the atoms of the body. As a result, the beam that leaves the body after crossing it has a defined pattern, where each area element has a density of photons that is different from its neighbors. These differences are caused due to more or less absorption of photons by the tissues that constitute the body. These different densities of x-ray photons can be translated by gray levels in an image, thus obtaining the radiography.

In the first years of radiography, glass bases coated with an x-ray sensible emulsion were used. The glass bases presented some disadvantages: they easily broke, possibly causing wounds to the person handling them; the processing was difficult and there was also the problem of keeping them for future references. With the introduction of flexible films these disadvantages were eliminated.

The x-ray film used currently is constituted by two basic components: the base and the emulsion. The base of the modern films is constituted by a transparent polyester sheet. The emulsion consists in microscopic crystals of silver halides suspended in a gelatinous substance. The emulsion is spread on the two sides of the polyester base, forming two layers sensible to the x-rays. After the beam, that crosses the body, falls upon the x-ray film, a latent image is registered on it and which is only visible after the processing. The processing of a film must be performed in a darkroom and can be divided into two steps: conversion of the latent image into a visible image and preservation of the visible image. The conversion of the latent image into a visible one is made by immersing the film in a chemical solution. Special attention must be paid regarding the temperature and time that the film is exposed to this solution. The preservation of the visible image consists mainly in removing the silver halides not exposed to the x-rays and to harden the emulsion, in order to prevent spoiling of the film. Once again, chemical solutions are used, being the temperature and the settling time very important for obtaining a good image.

The conventional radiographic image systems record and display their data in an analogical form. They frequently have very rigid exposition requirements due to the narrow brightness depth range of the films and very reduced hypotheses of image processing. The digital radiographic systems, on the other hand, offer the possibility of obtaining images with much less rigorous requirements of exposition than the analogical systems. The inaccuracies in terms of exposition often cause the appearance of too dark or too clear radiographies or with little contrast. These inaccuracies can be easily improved with digital techniques of image processing and display.

The systems of digital radiography, where the image will be shown on a screen, instead of the traditional process of displaying the film against the light, and where it is possible to digitally process the obtained image, present several advantages, such as the easy exhibition of the image; reduction of the radiation dose necessary to obtain a good image; simple processing of the image; possibility of acquisition of the image without delay times for the film processing; storage in electronic data bases, allowing easy browse and transmission for long distances, using communications networks.

One of the first digital x-ray imaging systems was based on a silicon device manufactured in CCD technology. The silicon has a very low x-ray absorption coefficient, but for each 1 MeV absorbed photon, there are produced about 277,000 electron-hole pairs, which allows obtaining images with enough quality for diagnostic with a radiation dose a little bit lower than the dose necessary to excite the silver halide films used in the traditional radiography. However, the small number of photons, detected by the CCD results in a significant quantum noise. In order to reduce the quantum noise, either the radiation dose or the quantum efficiency of the detector can be increased. Obviously the increase of the radiation dose is not desirable.

The quantum efficiency of the sensor can be increased by adding a scintillating layer above the CCD. A scintillator is a chemical compound that emits light when it is excited by radiation or high energy particles. The radiation is absorbed by the scintillating layer that has a high absorption coefficient, being subsequently converted into visible light (or into wavelengths close to the visible ones). As each x-ray absorbed photon is converted into many visible photons, the quantum efficiency of the detector is improved. The disadvantage is that this technique deteriorates the spatial resolution of the device, getting a value approximately equal to the thickness of the scintillating layer. This compels to a compromise between the thickness of the scintillating layer, which the larger it is, more x-ray photons absorbs, and the spatial resolution, which decreases with increasing thickness of the scintillating layer. This compromise, thickness of the scintillator-spatial resolution, can be improved with the technique of the light guides, which fabrication process is reported as an object of the present invention.

Recent developments regarding image detectors based on CMOS technology become more and more attractive in the development of image acquisition systems, when compared with devices based on CCD technology. In the same way, the digital radiography also benefits with the substitution of the CCDs by CMOS devices, as the devices based on CMOS technologies show the following characteristics:

operation power five to ten times minor than the CCDs and respective processing electronics;

the CMOS is a general purpose fabrication process while the CCD requires dedicated fabrication techniques;

the integration of the detector and the processing electronics in the same device is possible. In the CCD it is very difficult;

global cost five to ten times lower than for the CCD.

The characteristics of low cost and low power are highly desirable in portable applications and also in situations where the conventional x-ray devices are not possible, such as field hospitals or medical emergency vehicles.

As inconvenient of the substitution of the CCDs by CMOS devices one can point out the fact that it is still very difficult to obtain with the last ones images of the same quality when compared to the CCDs.

### STATE OF THE ART

In the medical industry, the efforts in the optimization of the radiography area are directed towards the developing of digital technology of the x-rays, using high efficiency electronic sensors in combination with advanced computer algorithms. Digital radiography allows the application of image processing techniques (detail improvement, for example), sophisticated algorithms (image subtraction, for example) and real time operation. Consequently, larger and larger efforts are directed in the sense of applying technologies, such as the microelectronics (microphotolithography and microfabrication), the micromachining and the study of new materials in order to develop devices using x-rays for diverse applications in the medical diagnosis.

The interest in an active matrix for digitally obtaining x-ray images is already a reality. These devices are already available in big sizes (bigger than 25×25 cm²) with pixel dimensions as small as 100×100 μm².

The panels of smaller dimensions are manufactured in silicon (CCD or CMOS technologies) and the bigger dimension ones in an amorphous silicon base, but due to relatively low absorption of x-rays by silicon (or amorphous silicon), an additional x-ray detection layer, at the top of the active matrix, is usually necessary. The materials that are generally used for this purpose can follow two approaches:

1. The first approach is an alternative to the indirect method and involves the use of a photoconductive layer, which forms the active matrix. In this approach, frequently called the direct method, the interactions between the radiation and the photoconductor produce electron-hole pairs. The electron-hole pairs are collected by the electrodes placed in the extremities of the photoconductor by means of an electric field. Thus, the photoconductors are in principle good candidates in order to construct the digital radiographic image sensor systems. However, this technology needs a high electric voltage for its operation and is incompatible with the silicon fabrication technologies, forcing the readout electronics to be placed in a separate device. As examples of this approach, patents US2005175911, WO2005036595, US2004152000, WO02061456, among others, can be cited.

2. The second approach, in which this invention integrates, involves the coupling of a scintillating layer to the photodetector matrix. This approach is usually referred to as indirect detection, once the x-ray energy is firstly converted into visible light, which is then detected by the photodetectors to produce the final image. In this approach, besides the scintillators, photodetectors to detect the visible light produced by the scintillators are necessary. There exist several works that propose different kinds of photodetectors for this goal, namely:

Photoconductors in CCD technology (for example, US2005151085, US2005058247, WO03045246);

Photoconductors in amorphous silicon (EP1475649 and WO0160236, among others);

Photomultiplier tubes (WO9614593 and U.S. Pat. No. 5,410,156, among others);

Avalanche photodiodes (U.S. Pat. No. 6,448,559 and U.S. Pat. No. 5,763,903, among others);

CMOS technology (WO03/032839 and U.S. Pat. No. 6,069,935, among others).

In these applications, the analog to digital converters are placed outside of the active pixel matrix.

With regard to the coupling between photodetectors and scintillators, as in the present invention, there exist some patents that propose architectures based on light guides. Their fabrication process is based on diverse techniques such as the fabrication of microcavities, which are then filled with a scintillating material. The cavities can be fabricated by chemical corrosion (US2004251420), with a laser (US2004042585) or by DRIE (U.S. Pat. No. 6,744,052). The opposite is also possible: open cavities in a scintillating crystal and fill them with a reflective material (US2002163992). The present invention distinguishes from these solutions, once the fabrication technique of the scintillating matrix embedded in reflective walls is based on a photolithographic process, allowing its quick fabrication and placement on the top of the photodetector matrix.

With respect to the photodetector matrix readout electronic circuits, which are also reported in the scope of the present invention, all known applications place the analog to digital converters outside the pixel active matrix. There exist some applications in CMOS technology (US2005173640 and U.S. Pat. No. 6,894,283, for example) and in bipolar technology (US2003105397). The present invention differentiates from these solutions since the photodetector matrix comprises an analog to digital converter for each pixel, which allows to obtain at its output a digital signal, immune to the noise sources characteristic of the analogical systems.

### BRIEF DESCRIPTION OF THE FIGURES

FIG. 1 shows a cross-sectional view of the proposed x-ray detector.

FIGS. 2 to 6 show different steps of the fabrication process.

FIG. 7 shows a block diagram of the photodetector matrix.

FIG. 8 shows a block diagram of each one of the photodetector matrix pixels (22).

FIG. 9 shows the circuit of the photodetector (21), of the amplifier (23) and of the integrator (24).

FIG. 10 shows the circuit of the one bit analog to digital converter.

FIG. 11 shows the circuit of the one bit digital to analog converter.

### DETAILED DESCRIPTION OF THE INVENTION

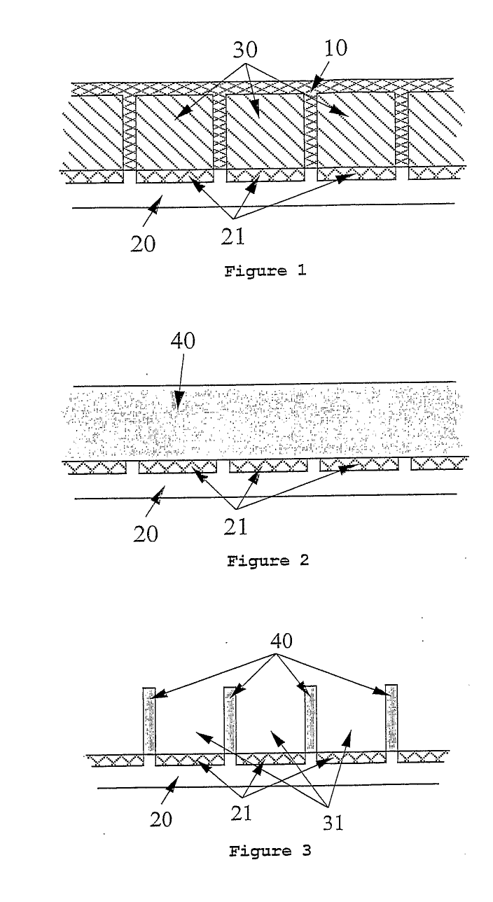

FIG. 1 shows a cross-sectional view of the x-ray detector matrix that consists in an image sensor (20), formed by a matrix of photodetectors (21), on which the matrix of scintillators (30), embedded in the reflectors (10), is placed. The radiation, coming from a radiation source placed above the detector, will penetrate in the reflector material (10) and reach the scintillators (30). The scintillators (30) will convert the radiation into visible light that is emitted in all directions. After a certain number of reflections, the visible light reaches the photodetectors (21), where it is detected.

The light guides prevent the dispersion of the visible light produced by the scintillators and the consequent interference between each pixel and its neighbors. It can be proved that the use of the light guides implies a much higher spatial resolution, as well as higher amplitude of the luminous signal that reaches the photodetector. As a higher amplitude of the luminous signal is obtained, this technique allows the reduction of the radiation dose necessary for the working of the device.

On the other hand, the amplifier and the analog to digital converter are located in each pixel, instead of being in the periphery of the matrix. This allows a reduction of the electronic noise generated by thermal processes or induced in the signal transport lines. As a consequence, the signal to noise ratio will increase, allowing an extra reduction in the radiation necessary for the device to work.

The fabrication process of the scintillator matrix inside of the reflective walls is shown in FIGS. 2 to 6.

In FIG. 2, the image sensor (20) constituted by the photodetector matrix fabricated in CMOS technology (21) is coated by the SU-8 light sensitive varnish (40). Above the light sensitive varnish, a mask is placed and upon ultraviolet light is applied. The parts of the varnish exposed to the light become hard, being then possible to remove the remaining parts, originating the pattern of FIG. 3. The use of a negative mask with a negative photosensitive varnish is also valid.

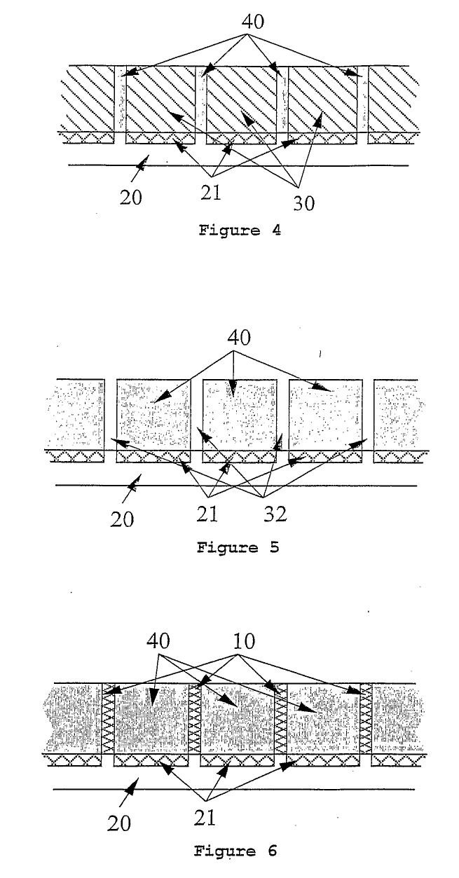

The following step will be the placement of the scintillator material, CsI:Tl (Cesium Iodide doped with Thallium) (30) in order to fill the cavities (31). This scintillator can be placed by evaporation, through a hot or cold mechanical pressure, in the form of crystalline powder or another form. In some cases, after the scintillator is being placed, it is necessary to apply a polishing operation in order achieve the result represented in FIG. 4. After this step, the light sensitive varnish (40) is totally removed and in the resultant cavities a reflecting material, aluminum (10), is placed by evaporation, cathodic spraying, or another process of material deposition. At the end of this step polishing is also necessary, so that the result will be the one represented in FIG. 1.

Another process to fabricate the device of FIG. 1 consists in using a mask constructed from the negative of the one used in FIG. 3 or alternatively a light sensitive varnish with opposing behavior to the one described in FIG. 3. In this in case, after the exposition to the light and the removal of the photosensitive varnish not hardened, the result will be the one of FIG. 5. After this step, the cavities (32) are filled with reflector material (10), originating the device of FIG. 6. Once again, depending on the deposition method of the reflector, it may be necessary to effectuate a polishing of the top after the deposition in order to obtain a device with the aspect of FIG. 6. After this, the photosensitive varnish (40) should be removed and the scintillator (30) must be placed in its place. In this case, an additional step will be necessary to place the reflector material on the top of the device, in order to become a device like the one presented in FIG. 1.

The fabrication process of the scintillator matrix should be performed above the photodetector matrix, previously fabricated in CMOS technology.

This photodetector matrix, manufactured in CMOS technology, uses an analog to digital converter for each pixel.

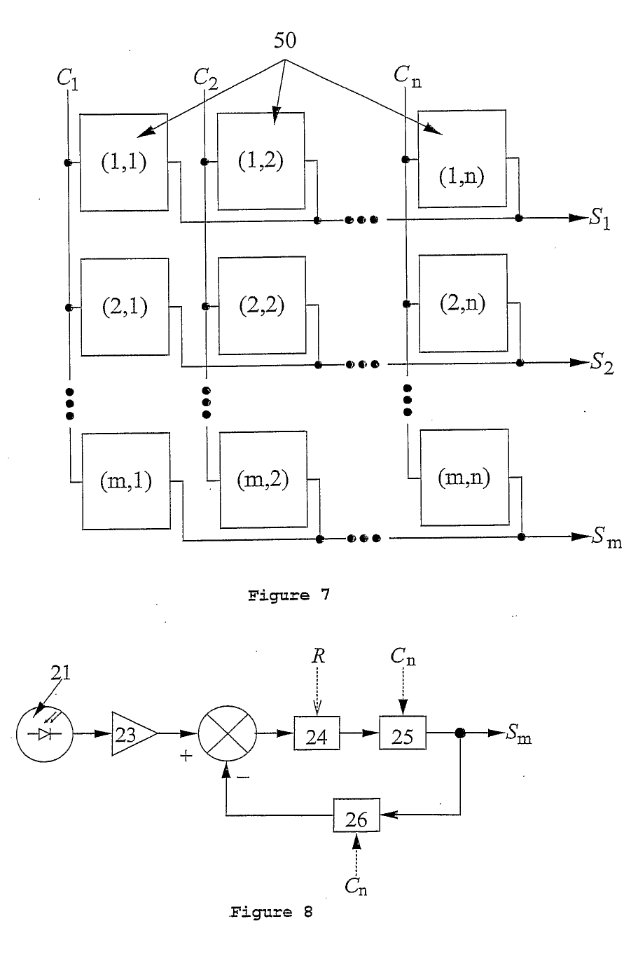

In FIG. 7, a block diagram of the matrix with an analog to digital converter for each pixel is shown. Each pixel (22) is constituted by a photodetector (21) and an analog to digital converter. The addressing of the columns is made using the clock signals, C₁, C₂, . . . , Cₙ, out of phase in time, being each pixel (22) connected to an output line. Each block of one pixel (22) converts the intensity of the light that it receives from the scintillator (30) in a digital code. This block is shown in detail in FIG. 8. As the output signal of each column is out of phase relatively to the remaining ones, each output line can be shared by the respective pixels. The working principle of the matrix is the following: the electric signal coming from the photodetectors (21) is amplified by the amplifier (23) and applied to the analog to digital converter. In order the last to have a good performance, the integrator (24) should be initialized by using the line R, so that the analog to digital converter starts at a known state. After the radiation falls upon the scintillators (30) and an image is focused in the photodetectors (21), the analog to digital converters of the sigma-delta type initiate the conversion and the result is read in all lines simultaneously. The oversampling frequency of the sigma-delta converter is determined by the desired signal to noise ratio.

The circuit can be divided in three parts: the integrator (24), the one bit analog to digital converter (25) and the one bit digital to analog converter (26).

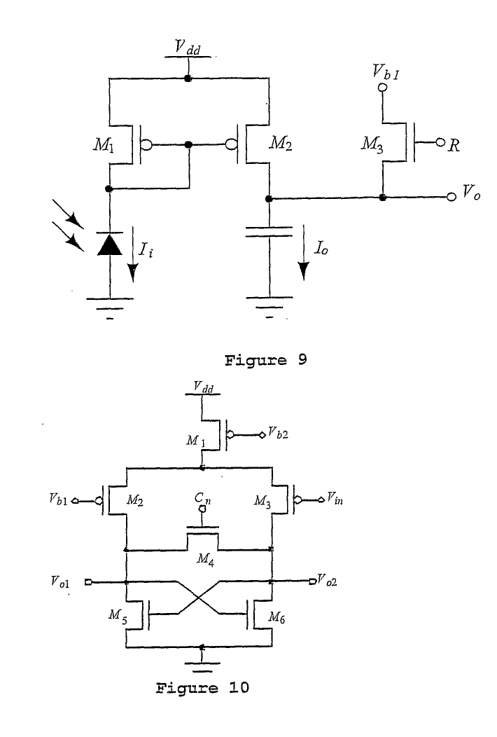

The circuits of the amplifier (23) and of the integrator (24) are based on a single current mirror, as it is illustrated in FIG. 9. The photodetector current flows through M₁. Since the voltages between the gates and the sources of M₁ and M₂ are equal, ideally a current proportional to Iᵢ circulates through M₂, if the two transistors operate in the saturation region. Disregarding the canal length modulation, the drain current of M₁ is given by:

$${I}_{D 1} = {I}_{i} = \frac{1}{2} {k}_{F}^{′} \frac{{W}_{1}}{{L}_{1}} {( {V}_{GS 1} - {V}_{tp} )}^{2} , \qquad ( 1 )$$

while the output current, assuming that M₂ is at saturation, is given by:

$${I}_{D2} = {I}_{o} = \frac{1}{2} {k}_{F}^{′} \frac{{W}_{2}}{{L}_{2}} {( {V}_{GS 2} - {V}_{tp} )}^{2} , \qquad ( 2 )$$

wherein I_{D 1} and I_{D 2} are the drain currents of the transistors M₁ and M₂, respectively, V_{GS 1} and V_{GS 2} are their voltages between gate and source, K′_{F}
is the transcondutance parameter of the p channel transistor and Vₜₚ is the conduction threshold voltage of the p channel transistor. Since V_{GS 1}=V_{GS 2}, the relationship between the two currents is given by:

$$\frac{{I}_{D 2}}{{I}_{D 1}} = \frac{{W}_{2} / {L}_{2}}{{W}_{1} / {L}_{1}} . \qquad ( 3 )$$

Equation 3 shows that, adjusting the widths (W) and the lengths (L) of the transistor channels, it is possible to amplify the photodetector (21) current. Since this current loads the capacitor and the voltage at its terminals is proportional to the integral of the current, the circuit also works as integrator.

The maximum output voltage is limited by the fact that M₂ must remain at the saturation, that is,

Vₒₘₐₓ=V_{DD}−V_{DSol}=V_{DD}−(V_{GS2}−Vᵣₚ) (4)

The output resistance of the current mirror is given by the resistance of M₂, that is,

$${r}_{o} = \frac{1}{λ {I}_{o}} , \qquad ( 5 )$$

(5) wherein λ is the channel length modulation parameter.

Also in the circuit of FIG. 9, M₃ is used to initialize the integrator, so that the sigma-delta converter starts to operate at a known state.

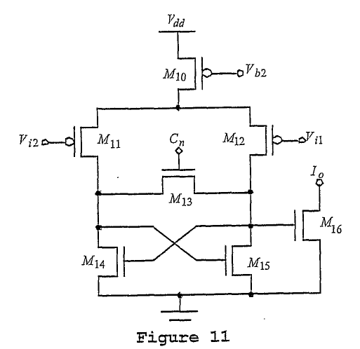

FIG. 10 shows the schematic diagram of the one bit analog to digital converter (25). Transistors M₅ and M₆ form a differential pair that amplifies the difference between Vᵢ and V_{b 1}, where Vᵢ is the output voltage of the integrator (24) and V_{b 1} is a reference voltage. The signal of this difference is stored in the memory formed by M₈ and M₆, at the negative transitions of the clock signal Cₙ. The state of this memory is kept while M₇ will be at the cutoff, that is, while the Cₙ signal will be at the low logical level.

The schematic diagram of the one bit digital to analog converter (26) is in FIG. 11. The working principle of the circuit is in everything identical to the one bit analog to digital converter. At the Vᵢ₁ and Vᵢ₂ inputs are connected the signals Vₒ₁ and Vₒ₂ coming from the one bit analog to digital converter (25). There is also the M₁₆ transistor, which works as a current to voltage converter, that is, it converts the digital output voltage into a current that will discharge the capacitor of the integrator, when such is justified.

1. Detector of radiation or of high energy particles composed of a scintillator matrix embedded in walls manufactured from a reflector material and a matrix of image elements (pixels), characterized by the fact that the scintillator matrix (30) embedded in reflector walls (10) is fabricated from a photolithographic process and each pixel of the photodetectors matrix is constituted by a photodetector (21), an amplifier (23) and an analog to digital converter.

2. A detector of radiation or of high energy particles, according to claim 1, characterized by the fact that the walls manufactured from the reflector material (10) form light guides to guide the visible light produced by the scintillators (30) placed in the matrix.

3. A detector of radiation or of high energy particles, according claim 1, characterized by the fact that the photodetector (21) might be a photodiode, a phototransistor or another one, manufactured in CMOS, bipolar or another technology.

4. A detector of radiation or of high energy particles, claim 1, characterized by the fact that the amplifier (23) might be based on a current mirror or on other circuit and fabricated in CMOS, bipolar or another technology.

5. A detector of radiation or of high energy particles, claim 1, characterized by the fact that the analog to digital converter might be of the sigma-delta type, a light-frequency converter, a flash converter, of slope or of another type, manufactured in CMOS, bipolar or another technology.

6. A Detector of radiation or of high energy particles, claim 1, characterized by the fact that the amplifier (23) and the analog to digital converter is located inside each pixel, instead of being in the periphery of the image elements matrix.

7. Photodetector matrix for the achievement of images from radiation or high energy particles, claim 1, characterized by being constituted by a photodiode, an amplifier (23) based on a current mirror and an analog to digital converter of the sigma-delta type, manufactured in CMOS technology.

8. Fabrication process of radiation or high energy particle detectors, claim 1, based on the indirect method characterized by the fact that the radiation or high energy particles are first converted into visible light by scintillators (30), consisting of a photolithographic process, with formation of cavities in a photosensitive varnish (40), through a mask and ultraviolet light.

9. A fabrication process of radiation or high energy particle detectors, according to claim 8, characterized by consisting in the following steps:
placement of the scintillators in the cavities of the photosensitive varnish;
substitution of the photosensitive varnish by a reflector material;
placement of the reflector material above the scintillator.

10. A fabrication process of radiation or high energy particle detectors, according to claim 8, characterized by consisting in the following steps:
placement of the reflector material in the cavities;
substitution of the photosensitive varnish by scintillator material;
placement of the reflector material above the scintillator.

11. A fabrication process of radiation or high energy particle detectors, according to claim 9, characterized by the fact that the scintillator is placed by evaporation, hot or cold pressure, or by another technique of material deposition, and by the fact that the reflector also might be placed by evaporation, cathodic spraying, or another technique of material deposition.

12. Use of matrices, according to claim 7, characterized by being applied in the fabrication of radiation or high energy particles detector devices.

13. Use of radiation or high energy particle detector devices, according to claim 1, characterized by applying them for obtaining digital radiographic images.

14. Use of radiation or high energy particle detector devices, according to claim 1, characterized by being applicable to the analysis of digital radiological images, in the medical field and scientific research as, for example, but not exclusively, to molecular biology, and in non destructive industrial tests.
